(19) United States
(12) Patent Application Publication
(10) Pub. No.: US 2011/0223748 A1
(43) Pub. Date: Sep. 15, 2011

(54) METHOD FOR PHASE TRANSITION OF AMORPHOUS MATERIAL

(75) Inventors: Jin Jang, Seoul (KR); Jae-Hwan Oh, Seoul (KR); Dong-Han Kang, Seoul (KR); Jun-Hyuk Cheon, Seoul (KR)

(73) Assignee: KYUNGHEE UNIVERSITY INDUSTRIAL & ACADEMIC COLLABOR, Seoul (KR)

(21) Appl. No.: 13/063,182

(22) PCT Filed: May 19, 2009
(86) PCT No.: PCT/KR2009/002625

§ 371 Date: May 31, 2011

(30) Foreign Application Priority Data
Sep. 9, 2008 (KR) 10-2008-0088855

(51) Int. Cl. H01L 21/20

(52) U.S. Cl. 438/487; 257/E21.133

(57) ABSTRACT

Disclosed herein is a method of crystallizing an amorphous material for use in fabrication of thin film transistors. The method includes forming an amorphous silicon layer on a substrate, depositing a Ni metal layer on part of the amorphous silicon layer, and heat-treating the amorphous silicon layer to cause phase transition of the amorphous silicon, wherein the Ni metal layer is deposited to an average thickness of 0.79 Å or less. The method can crystallize an amorphous material for use in thin film transistors using the metal induced lateral crystallization while restricting thickness and density of Ni, thereby minimizing current leakage in the thin film transistor.

### TECHNICAL FIELD

The present invention relates to a method of crystallizing an amorphous material for use in fabrication of thin film transistors and, more particularly, to a metal induced lateral crystallization (MILC) method.

### BACKGROUND ART

Thin film transistors (TFTs) refer to a switching element that employs a poly-crystalline silicon thin film as an active layer, and are generally used for active elements of active matrix liquid crystal displays and switching elements and peripheral circuits of electric light emitting devices.

In general, the thin film transistor is fabricated by direct deposition, high temperature heat treatment or laser heat treatment. Particularly, the laser heat treatment is preferred to the other processes due to merits such as crystallization (also referred to as phase transition) at low temperatures of 400° C. or less and high field effect mobility. However, the laser heat treatment is not suitable for fabrication of polycrystalline silicon on a large area substrate due to problems such as non-uniform phase transition, use of expensive systems, and low yields.

As another method for crystallization of an amorphous material, particularly, amorphous silicon, a solid phase crystallization (SPC) method is employed to form crystals through uniform phase transition using an inexpensive system. In this method, however, crystallization requires a long period of time causing low productivity and is performed at high temperature making it difficult to use a glass substrate.

On the other hand, phase transition of an amorphous material using metal has been widely studied due to its rapid phase transition at low temperature compared with the SPC method. An example of this method is metal induced crystallization (MIC).

In the MIC method, a predetermined kind of metal is brought into direct contact with an upper surface of an amorphous material thin film to allow lateral phase transition to start from part of the thin film contacting the metal, or a predetermined kind of metal is injected into the amorphous material thin film to allow phase transition of the amorphous material to start from the injected metal. Specifically, this method is based on a phenomenon that phase transition from amorphous silicon to polycrystalline silicon is induced even at a low temperature of about 200° C. when a metal such as nickel, gold, aluminum or the like is brought into contact with the amorphous silicon or is injected into the amorphous silicon. In this method, however, when the thin film transistor is fabricated, some metallic components remain in the polycrystalline silicon constituting an active layer of the transistor, thereby causing current leakage in a channel region of the transistor.

Accordingly, instead of inducing direct phase transition of amorphous silicon using metal as in the MIC method, it has been proposed in recent years to employ a Metal Induced Lateral Crystallization (MILC) phenomenon for crystallization of an amorphous silicon layer, in which sequential crystallization of amorphous silicon is induced through continuous lateral propagation of silicide produced by reaction between metal and silicon.

Examples of the metal inducing the MILC phenomenon include nickel and palladium. When crystallizing an amorphous silicon layer based on the MILC phenomenon, no metallic component substantially remains in the crystallized silicon layer that is obtained using the MILC phenomenon, in which a silicide interface containing a metal moves laterally due to propagation of phase transition of the amorphous silicon layer, so that current leakage can be suppressed in the active layer of the thin film transistor. However, this method does not completely solve the problem of current leakage, either. Therefore, there is a need for a method capable of minimizing current leakage in the thin film transistor.

### DISCLOSURE OF INVENTION

Technical Problem

The present invention is directed to solve the problem of the related art as described above, and an aspect of the present invention is to provide a method of crystallizing an amorphous material for use in fabrication of a thin film transistor using metal induced lateral crystallization while restricting thickness and density of Ni, thereby minimizing current leakage in the thin film transistor.

Technical Solution

In accordance with an aspect of the present invention, a method for phase transition of an amorphous material includes forming an amorphous silicon layer on a substrate, depositing a Ni metal layer on part of the amorphous silicon layer, and heat-treating the amorphous silicon layer to cause phase transition of the amorphous silicon, wherein the Ni metal layer is deposited to an average thickness of 0.79 Å or less.

In accordance with another aspect of the invention, a method for phase transition of an amorphous material includes forming an amorphous silicon layer on a substrate, depositing a Ni metal layer on part of the amorphous silicon layer, depositing an insulation material including a silicon oxide layer on the amorphous silicon, and heat-treating the amorphous silicon layer to cause phase transition of the amorphous silicon, wherein the Ni metal layer is deposited to an average thickness of 0.79 Å or less.

In accordance with a further aspect of the invention, a method for phase transition of an amorphous material includes forming an amorphous silicon layer on a substrate, and depositing a Ni metal layer on part of the amorphous silicon layer, followed by heat-treating the amorphous silicon layer to cause phase transition of the amorphous silicon, wherein a crystalline structure under the Ni metal layer forms a polygon.

According to an embodiment of the present invention, the Ni metal layer has a Ni density of 3.4×10¹³/cm²˜7.3×10¹⁴/cm².

Advantageous Effects

According to exemplary embodiments of the invention, the method can crystallize an amorphous material for use in fabrication of a thin film transistor using metal induced lateral crystallization while restricting thickness and density of Ni, thereby minimizing current leakage in the thin film transistor.

### BRIEF DESCRIPTION OF DRAWINGS

The above and other aspects, features and advantages of the present invention will be more clearly understood from the following detailed description taken in conjunction with the accompanying drawings, in which:

FIG. 1 is a flow diagram illustrating crystallization of amorphous silicon based on Ni-MILC;

FIG. 2 is a flow diagram of a method for phase transition of an amorphous material based on MILC according to one embodiment of the present invention;

FIG. 3 is photomicrographs of silicon polycrystals obtained MILC-based crystallization by the method according to the embodiment of the present invention;

FIG. 4 is graphs depicting current leakage according to Ni density during MILC-based crystallization by the method according to the embodiment of the present invention; and

FIG. 5 is a graph depicting field effect mobility and electric current in a minimal-off state according to Ni density.

### BEST MODE FOR CARRYING OUT THE INVENTION

According to an embodiment of the present invention, a method for phase transition of an amorphous material based on metal induced lateral crystallization includes forming an amorphous silicon layer on a substrate, depositing a Ni metal layer on part of the amorphous silicon layer, and heat-treating the amorphous silicon layer to cause phase transition of the amorphous silicon, wherein the Ni metal layer is deposited to an average thickness of 0.79 Å or less.

Mode for the Invention

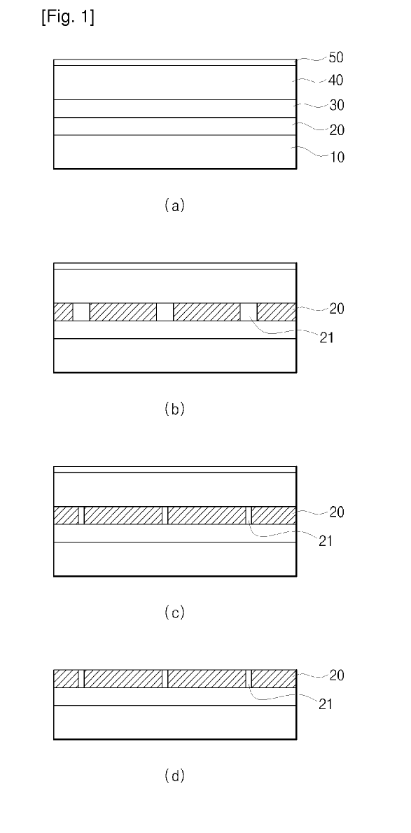

FIG. 1 is a flow diagram illustrating crystallization of amorphous silicon based on Ni-MILC.

In a method for phase transition of an amorphous material for use in fabrication of a thin film transistor according to an embodiment of the invention, the thickness of a metal deposited on a substrate is adjusted during metal induced lateral crystallization used for crystallization of the amorphous material, thereby minimizing current leakage.

Next, the metal induced lateral crystallization (MILC) used for this method will be described.

First, crystallization of an amorphous material through a metal induced crystallization (MIC) process generally used as a preceding process for the MILC will be described.

Referring to FIG. 1, after a buffer layer 20 is formed on a substrate 10, an amorphous silicon layer 30 is deposited on the buffer layer 20. Then, a silicon oxide layer is formed as a cover layer 40 on the amorphous silicon layer 30 and a metal 50 is deposited on the cover layer.

Although not limited to a particular material, the substrate may be a single crystal wafer that is covered with glass, quartz or an oxide film to obtain uniform thickness and uniform temperature for phase transition of the amorphous material. According to this embodiment of the invention, the substrate is a glass substrate.

Although the buffer layer 20 can be omitted from this process, the buffer layer 20 may be formed of a silicon oxide layer in this embodiment of the invention.

Further, the amorphous material is not limited to a single specific material and amorphous silicon (a-Si) may be used as the amorphous material.

The cover layer 40 is formed of the silicon oxide layer on the amorphous silicon layer.

The metal 50 is deposited on the cover layer and may include, but is not limited to, Ni, Pd, Au, Cu, Al, and the like. According to this embodiment of the invention, Ni is used as the metal to be deposited on the cover layer.

As such, in the method according to this embodiment of the invention, the substrate 10, the buffer layer 20, the amorphous material 30, the cover layer 40 and the metal 50 are sequentially laminated on top of one another, followed by heat treatment to crystallize amorphous silicon used as the amorphous material, thereby forming a crystallized silicon layer 31. Specifically, when the laminate structure is subject to heat treatment for a long duration, the metal, that is, Ni, diffuses into the amorphous silicon to form grains of metal silicide NiSi₂, which in turn grows laterally. Then, as the heat treatment is continued, the respective grains continue to grow, thereby allowing complete phase transition of the amorphous material into polycrystals. After complete phase transition of the amorphous material, the metal 50 and the cover layer 40 are removed by etching, thereby providing a polycrystalline thin film.

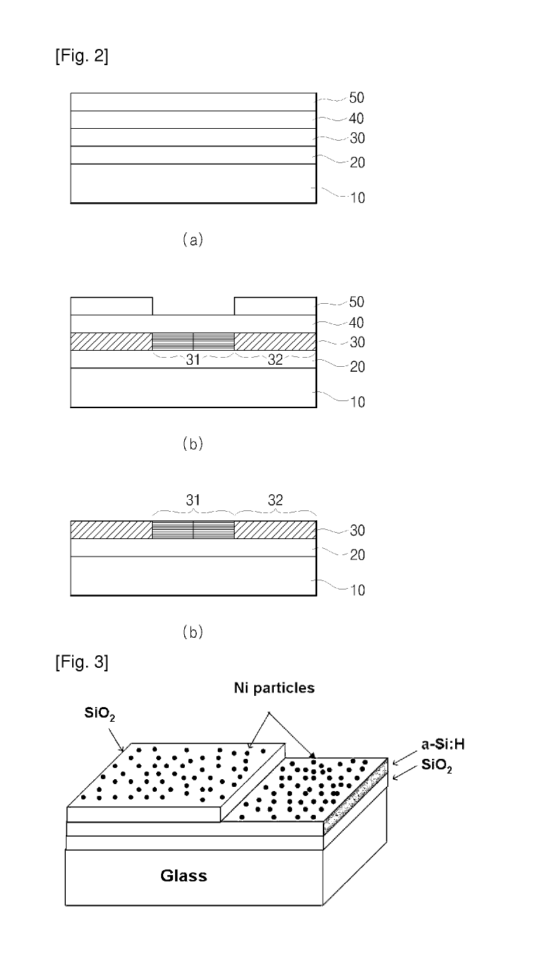

Next, a metal induced lateral crystallization (MILC) method using the metal induced crystallization process according to one embodiment of the present invention will be described with reference to FIG. 2.

In the metal induced lateral crystallization method using the MIC process, no metal component used for crystallization induction substantially remains due to the phenomenon that a metal silicide interface containing a metal moves laterally according to propagation of phase transition of an amorphous silicon layer. As a result, deposition of the metal does not cause current leakage in an active layer of the transistor and has no influence on other operating characteristics of the transistor while inducing crystallization of the amorphous silicon at low temperature. Therefore, the MILC method according to the invention enables crystallization of plural substrates at the same time using a furnace without damage to the substrates.

According to one embodiment of this invention, the MILC method may include forming an amorphous silicon layer on a substrate, depositing a Ni metal layer on part of the amorphous silicon layer, and heat-treating the amorphous silicon for phase transition thereof. According to another embodiment of this invention, the MILC method may include forming an amorphous silicon layer on a substrate, depositing a Ni metal layer on part of the amorphous silicon layer, and depositing an insulation material including a silicon oxide layer on the amorphous silicon, followed by heat-treating the amorphous silicon for phase transition thereof.

Further, according to a further embodiment of this invention, the MILC method may include forming an amorphous silicon layer on a substrate, depositing a Ni metal layer on part of the amorphous silicon layer, and heat-treating the amorphous silicon layer to cause phase transition of the amorphous silicon, wherein a crystalline structure under the Ni metal layer forms a polygon.

Next, the method according to one of the aforementioned embodiments will be described in more detail.

Basically, after a buffer layer 20 is formed on a substrate 10, an amorphous material layer (for example, a-silicon) 30 and a cover layer (i.e. a silicon oxide layer) 40 are sequentially formed on the buffer layer 20, followed by deposition of a metal (for example, Ni) layer 50 for facilitation of crystallization (see (a) of FIG. 2).

In this case, a dopant may be injected into the amorphous material to form source, channel and drain regions.

Particularly, the channel region is formed by patterning the metal layer and is subjected to heat treatment as described above. During the heat treatment, Ni particles grow into grains, so that crystallization from the amorphous material layer 30 to a crystallized layer 32 starts. Then, in a region of the amorphous material layer which can be used as the channel region, crystallization proceeds from an interface of the crystallized layer 32 to a region 31 of the amorphous material layer with no metal layer thereabove. As such, when the region 31 of the amorphous material layer with no metal layer thereabove is crystallized by crystallization from the crystallized layer 32 toward the center of the amorphous material layer through MIC of a lateral part, the region 31 of the amorphous material layer with no metal layer thereabove substantially has no metallic impurities, thereby exhibiting good properties. Then, the region 31 serves as the channel region after being crystallized, and the crystallized regions 32 at both sides of the region 31 serve as the source/drain regions.

In this embodiment of the invention, Ni is used as the metal for facilitation of crystallization and may be deposited to an average thickness of 0.037˜10 Å. According to one embodiment of this invention, Ni may be deposited to a thickness of 0.79 Å or less. When the metal layer has a thickness of 0.79 Å or less, current leakage is considerably reduced.

The metal deposition may be achieved by PECVD, but is not limited thereto. According to one embodiment of the present invention, Ni may be deposited at a density of 3.4×10¹³/cm²˜7.3×10¹⁴/cm².

Table 1 shows effects according to density of a metal layer in the present invention. Specifically, it can be seen from Table 1 that current leakage in an off-state and field effect mobility were considerably enhanced by depositing Ni at a density of 7.3×10¹⁴/cm² or less.

TABLE 1

| Ni area density | Field effect | Threshold voltage | S |
|---|---|---|---|
| (atoms/cm²) | mobility (cm²/Vs) | (V) | factor (V/decade) |
| 3.4 × 10¹³ [symbol] | 49.2 | −6.7 | 0.69 |
| 1.4 × 10¹⁴ [symbol] | 53.5 | −6.3 | 0.72 |
| 7.3 × 10¹⁴ [symbol] | 42.0 | −6.7 | 0.76 |
| 9.1 × 10¹⁵ [symbol] | 12.5 | −10.5 | 1.28 |

FIG. 3 shows photomicrographs of silicon polycrystals obtained by annealing at 580° C. for 20 hours after depositing Ni at area densities of (a) 3.4×10¹³/cm², (b) 1.4×10¹⁴/cm², (c) 7.3×10¹⁴/cm², and (d) 9.2×10¹⁵/cm², respectively.

In each of the photomicrographs, (A) indicates an amorphous silicon region, (B) indicates an MILC-based crystallization region, and (C) indicates an MIC-based crystallization region. As described above, crystallization proceeds from the MIC-based crystallization region (C) to the region (B).

FIG. 3 (a) shows grains in the region (C) under crystallization.

The MILC-based crystallization region (B) has a length of 52 μm in (a), but has a length of 120 μm in (b) to (d).

This result indicates that the longer for crystallization proceeds, the longer the length of the MILC-based crystallization region.

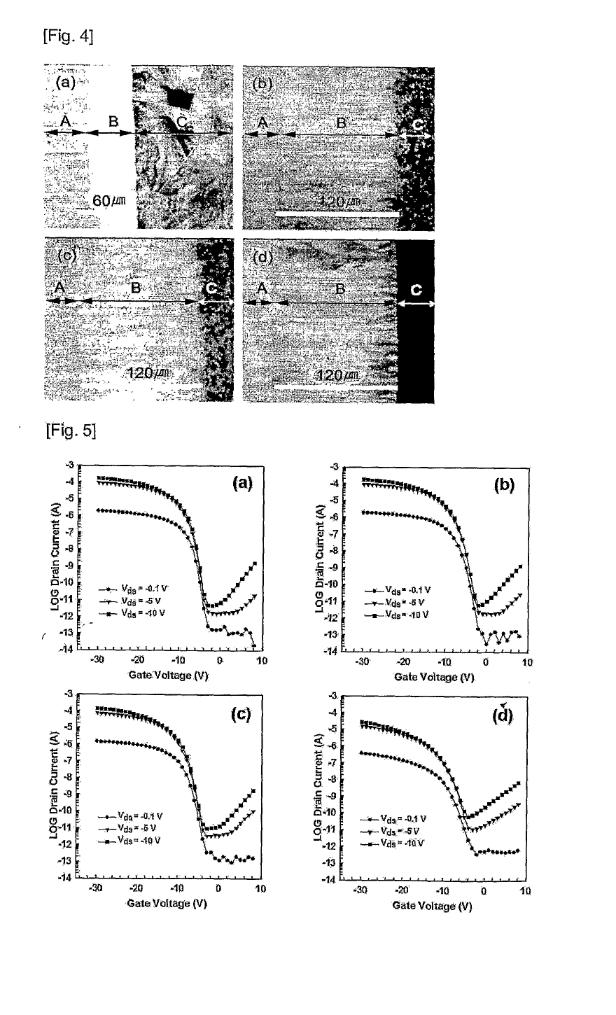

FIG. 4 is graphs depicting current leakage according to Ni density during crystallization when depositing Ni at densities of (a) 3.4×10¹³/cm², (b) 1.4×10¹⁴/cm², (c) 7.3×10¹⁴/cm², and (d) 9.2×10¹⁵/cm², respectively. In any case, current leakage in an off-state was decreased along with a decrease of the Ni density.

FIG. 5 is a graph depicting field effect mobility and electric current in a minimal-off state according to Ni density. The field effect mobility is obtained from mutual conductance in a linear area at V_{ds} (=−0.1V) using Equation 1.

$${g}_{m} = \frac{\partial {I}_{d}}{\partial {V}_{g}} = {C}_{i} {V}_{d} {μ}_{fe} \frac{W}{L} \qquad [ Equation 1 ]$$

(where Cᵢ and W/L indicate capacitance of a gate insulator and a ratio of width to length of a thin film transistor)

It can be seen from FIG. 5 that an increase in Ni density leads to a decrease in field effect mobility and an increase in current in the minimal-off state. In other words, when the Ni density increases in a polycrystalline silicon thin film, imperfections increase in the thin film, thereby increasing current leakage. FIG. 5 shows that the current leakage can be reduced by decreasing the Ni density to 7.3×10¹⁴/cm² or less. Therefore, according to the present invention, the current leakage can be considerably reduced by depositing Ni at a density in the range of 3.4×10¹³/cm²˜7.3×10¹⁴/cm².

As apparent from the above description, a TFT fabricated by the MILC method according to the present invention can minimize current leakage in the TFT by properly restricting the area density and thickness of Ni.

Although some exemplary embodiments have been provided to illustrate the present invention, it should be noted that the present invention is not limited to the embodiments and that various modifications, additions and substitutions can be made by a person having ordinary knowledge in the art without departing from the scope of the invention. Therefore, the spirit and scope of the present invention should be limited only by the accompanying claims and equivalents thereof.

### INDUSTRIAL APPLICABILITY

The present invention provides a method for crystallization of an amorphous material for use in fabrication of a thin film transistor using metal induced lateral crystallization while restricting thickness and density of Ni to minimize current leakage in the thin film transistor.

1. A method for phase transition of an amorphous material, comprising: forming an amorphous silicon layer on a substrate;
depositing a Ni metal layer on part of the amorphous silicon layer; and
heat-treating the amorphous silicon layer to cause phase transition of the amorphous silicon,
wherein the Ni metal layer is deposited to an average thickness of 0.79 Å or less.

2. A method for phase transition of an amorphous material, comprising:
forming an amorphous silicon layer on a substrate;
depositing a Ni metal layer on part of the amorphous silicon layer; and
depositing an insulation material including a silicon oxide layer on the amorphous silicon, followed by heat-treating the amorphous silicon layer to cause phase transition of the amorphous silicon,
wherein the Ni metal layer is deposited to an average thickness of 0.79 Å or less.

3. A method for phase transition of an amorphous material, comprising:
forming an amorphous silicon layer on a substrate;
depositing a Ni metal layer on part of the amorphous silicon layer; and
heat-treating the amorphous silicon layer to cause phase transition of the amorphous silicon,
wherein a crystalline structure under the Ni metal layer forms a polygon.

4. The method according to any one of claims 1 to 3, wherein the Ni metal layer has a Ni density of 3.4×10¹³/cm²˜7.3×10¹⁴/cm².
